(19) United States
(12) Patent Application Publication
(10) Pub. No.: US 2004/0227144 A1
(43) Pub. Date: Nov. 18, 2004

(54) Novel light-emitting device

(75) Inventor: Schang-Jing Hon, Pa Te City (TW)

Correspondence Address: TROXELL LAW OFFICE PLLC, SUITE 1404, 5205 LEESBURG PIKE, FALLS CHURCH, VA, 22041, US

(73) Assignee: Super Nova Optoelectronics Corp.

(21) Appl. No.: 10/693,863

(22) Filed: Oct. 28, 2003

(30) Foreign Application Priority Data
Oct. 28, 2002 (TW) 091132001

(51) Int. Cl. H01L 27/15; H01L 31/12; H01L 33/00

(52) U.S. Cl. 257/87

(57) ABSTRACT

A manufacturing method and a thus produced white colored and a specified colored light-emitting devices (LEDs) are disclosed. The white colored LED includes a resonant cavity structure, producing and mixing lights which may mix into a white colored light in the resonant cavity structure, so that the white colored LED may be more accurately controlled in the hue of the generated white colored light, which efficiently reduces deficiency, generates a natural white colored light and aids in luminous efficiency promotion. The specified colored LED is obtained in the similar manner as the white colored LED. In addition to the resonant cavity structure, the light-emitting device also includes a contact layer, an n-type metal electrode and a p-type metal electrode.

### BACKGROUND OF THE INVENTION

1. Field of the Invention

The present invention pertains to a white colored and a specified colored light-emitting devices (LEDs), and particularly to a manufacturing method and a thus produced light-emitting device for the light-emitting devices. In particular, the light-emitting devices of the LEDs concerned herein are based on the III-V group GaN-based materials and have each a resonant cavity structure used to adjust chromaticity of the produced light.

2. Description of Related Art

Light-emitting devices (LEDs) have been developed and on the market for years and are useful in providing lights as generally recognized. The use of LEDs in digital watches and calculators are well known. As we see, it may also find other important applications in communications and other areas, such as mobile phone and some appliances. Recently, there is a trend that LEDs be further applied to ordinary human living utilization, such as large panels, traffic lights and lighting facilities and the perspective thereof are looking good. Therefore, LEDs are increasingly playing an important role in our daily life and deserving our more efforts. As is transparent to those skilled in the art, LEDs are produced based on some semiconductor materials and emits lights by dint of the behaviors aroused in the semiconductor materials in the presence of an applied electrical bias.

In particular, an LED gives off a light by a light-emitting device therein generally composed of some III-V group (compound) semiconductors owing to its stronger inclination of recombination of electrons and holes. In principle, an LED is basically a well-known p-n junction structured device, i.e., a device having a p region, an n region and a transient region therebetween. With a forward voltage or current bias applied, the majority of carriers in the p or n regions drift respectively towards the other region (through the transient region) in the device due to the energy equilibrium principle and a current is accounted for, in addition to the general thermal effects. When electrons and holes jumped into a higher value of energy band with the aid of electrical and thermal energy, the electrons and the holes recombine there and give off lights when they randomly and spontaneously fall back to a reduced energy state owing to thermal equilibrium principle, i.e. spontaneous emission.

Afterwards, the concept and structure widely used in semiconductor device of the multi-quantum well (MQW) layers are introduced into an LED structure. Generally, the MQW layers are formed between the p and the n regions in the above-mentioned p-and-n structure. With the aid of the MQW active layers, the possibility of recombination of the electrons and holes in the P-I-N junction based device are efficiently enhanced and the luminous efficiency thereof is upgraded considerably. Further, color of a light emitted from the LED may be controlled through the choice of the materials, dopant concentration and layer thickness in the MQW layers.

For the recent years, not only red, green and blue lights are successively set forth, but a white colored light has been achieved in an LED. However, the white colored LED of the state of the art suffers some drawbacks, which can be recognized by ordinary people and those skilled in the relevant art. These shortcomings inhered in the currently existed white colored LED will be described in detailed in the following, and the incentive the present invention is provided may be thus well understood.

In U.S. Pat. No. 5,998,925, invented by Shimizu et al., entitled “LIGHT EMITTING DEVICE HAVING A NITRIDE COMPOUND SEMICONDUCTOR AND A PHOSPHER CONTAINING A GARNET FLUORESCENT MATERIAL” disclosed a white colored light-emitting device comprising a light-emitting component using a semiconductor as a light emitting layer and a phosphor which absorbs a portion of light emitted by the light emitting component and emits a light of wavelength different from that of the absorbed light, wherein the light emitting layer of the light emitting component is a nitride compound semiconductor and the phosphor contains garnet fluorescent material activated with cerium. The light emitted by the light-emitting component has a wavelength belonging to the blue light range (470 nm), and the light emitted by the activated phosphor has a wavelength of 550 nm falling within the yellow light range. Since the phosphor is applied on the package of the LED, the produced blue and yellow lights are mixed by virtue of the package and a white colored light is thus formed and reached to a user's eyes. Referring to the chromaticity diagram shown in FIG. 16, one may understand that the mixed color is located along the line L1, formed by connection of point a (corresponding to a wavelength of 470 nm) and point a′ (corresponding to a wavelength of 550 nm). Further, the real point that the mixed light locates runs along L1, i.e. when intensity of the blue light and the yellow light is varied the real operating point will also shift. However, such a prior white colored LED has encountered some problems in operation:

(1) Chromaticity produced is not easy to control: phosphor is difficult to be controlled in its applied amount. Once the light emitting material is given, the emitted blue light will be fixed also. Next, phosphor should be applied on the package to be activated and then a yellow light may be given off. However, the phosphor amount should be advertently adjusted; otherwise, the mixed light would not be a white colored light exactly as desired. In real implementation, however, the added amount of the phosphor is hard to be controlled and the mixing result can only be known after a package is manufactured and applied thereon, i.e., the light control operation should be involved with the packaging stage proceeding after the mere LED structure is completed. Therefore, chromaticity of the resulting light is apt to be not accurate and thus increase the rate of deficiency.

(2) An unnatural white colored light may unavoidably produce: through the line L1 of FIG. 16, it is easy to understand the mixed light resulted from the afro-mentioned light emitting device is not totally like a natural light. In a thus made white colored light. In this case, the obtained color may be observed with an error with respect to an object through a use of a photodetector, a camera, a photo-recorder or a scanner, which is blue-apt or green-apt.

(3) Luminous efficiency is insufficient: since phosphor is inhered with a significant absorptive behavior, the corresponded luminous efficiency still leaves room to be upgraded.

(4) A thus produced white colored LED leads to shorter lifetime: as generally known, phosphor has a limited lifetime when it is subject to a long time use; for example, 8,000 hr. Specifically, the phosphor will attenuate in amount and vary in characteristics, and hence the generated yellow and thus the mixed white colored lights will gradually change in its color. In short, the lifetime of the light emitting device is strongly limited by the applied short lifetime of phosphor.

U.S. Pat. No. 6,337,536, invented by Matsubara et al., entitled “WHITE COLOR LIGHT-EMITTING DEVICE AND NEUTRAL COLOR LIGHT-EMITTING DEVICE” disclosed a white colored or neutral colored LED, having an n-type ZnSe single crystal substrate doped with I, Cl, Br, Al, Ga or In as SA-emission centers and an epitaxial film structure including a ZnSe, ZnCdSe or ZnSeTe active layer and a pn-junction. The active layer emits blue or bluegreen light. The SA-emission centers in the ZnSe substrate convert blue or bluegreen light to yellow or orange SA-emission. The blue or bluegreen light from the epitaxial film structure and the yellow or orange light from the ZnSe substrate synthesize white color light or neutral color light between red and blue. However, this prior device may not reach what has long been expected with respect to its luminous efficiency (about 8 lm/W) and lifetime (about 8,000 hr).

In view of the foregoing problems, a white colored light-emitting device which may produce a natural light, yield a high throughput, have a long lifetime and possess a high luminous efficiency is still in need and expected to be set forth. All these needs create a stimulus pushing the inventors of the present invention toward providing a new white colored LED.

### SUMMARY OF THE INVENTION

It is therefore an object of the present invention to provide a light-emitting device for a white colored LED, which may be free from the disadvantages present in the above-mentioned prior devices, and its manufacturing method. Such a white colored LED is improved in chromaticity adjustment and has not involvement with phosphor, which generally places a limitation on the lifetime, luminous efficiency and chromaticity of the LED and can only be adjusted in amount after the whole light emitting structure is finished. At the same time, it is also an object of the present invention to provide a light-emitting device for a specified colored LED, which is made in principle similar as the white colored LED.

To achieve the object of the present invention, the light-emitting device for a specified colored LED device is provided with a resonant cavity comprising two multi-quantum well (MQW) active layers, wherein a second MQW layers may be excited by a first light generated from a first MQW layer in the LED and then emits a second light with a wavelength of the second light longer than that of the first light's, and the first and the second lights may mix into a specified colored light, which may be, for example, white colored light. In a preferred embodiment, the first light is a blue light and the second light is a yellow light.

In the light-emitting device, a resonant cavity, a contact layer, an n-type electrode and a p-type electrode are included. In the resonant cavity of a preferred embodiment, besides a substrate, a buffer layer, an n-GaN based layer and a p-GaN based layer, a distributed Bragg reflector (DBR) and a metal reflector are provided over the n-GaN based layer and below the substrate respectively for resonation of lights therein with appropriate reflectance of the DBR and the metal reflector. To obtain specified wavelengths of the first and second lights, the materials of both the first and second MQW active layers, such as InGaN/GaN, and their concentrations of In dopant may be chosen. In a preferred embodiment of the white colored LED, the first light has a wavelength of 450-510 nm while the second light bears a wavelength of 550-650 nm.

In some embodiments, the metal reflector may be replaced with an n-type DBR as a lower reflecting component and formed over an upper surface of the substrate. In a preferred embodiment, a transparent contact layer (TCL) is coated over the contact layer for uniformly spreading the charges instilled from the p-type electrode into the entire p-GaN based contact layer. And since the TCL is the last layer except for the p-type electrode in light extraction's view, the TCL may be termed as a window layer.

The manufacturing method according to a preferred embodiment of the present invention comprises: (a) forming a second MQW active layer over a substrate; (b) forming an n-GaN based epitaxial layer over said second MQW active layer; (c) forming a first MQW layer over said n-GaN based epitaxial layer; (d) forming a p-type distributed Brag reflector (DBR) over said first MQW active layer; (e) forming a p-GaN based layer over said p-type DBR; and (f) coating a metal reflector on a bottom side of said substrate. In another embodiment, the step (f) may be removed and a step (g) may be incorporated in the step (a) by first forming an n-type DBR over the substrate and then forming the second MQW active layer over the n-type DBR.

With the proposed white colored LED light-emitting device, the chromaticity control of the generated white colored light may be performed better, the generated light is more like a natural light, the light generation has a higher luminous efficiency and the device has a high yield and thus a reduced cost owing to the absence of phosphor but the resonant cavity.

### BRIEF DESCRIPTION OF THE DRAWINGS

To better understand the other features, technical concepts and objects of the present invention, one may read clearly the description of the following preferred embodiment and the accompanying drawings, in which:

FIG. 1 depicts schematically a manufacturing method of a preferred embodiment according to the present invention;

FIG. 2 depicts schematically a structure of a light-emitting device of a preferred embodiment according to the present invention;

FIGS. 3 and 3A represent a particular example of the epitaxial structure shown in FIG. 2;

FIG. 4 is an example of chromaticity diagram resulted from a white colored LED according to the present invention;

FIG. 5 depicts schematically a manufacturing method of a second embodiment according to the present invention;

FIG. 6 depicts schematically a structure of a light-emitting device of a second embodiment according to the present invention;

FIG. 7 depicts a particular example of the epitaxial structure shown in FIG. 6;

FIG. 8 depicts schematically a manufacturing method of a third embodiment according to the present invention;

FIG. 9 depicts schematically a manufacturing method of a fourth embodiment according to the present invention;

FIG. 10 depicts schematically a structure of a fourth embodiment according to the present invention;

FIG. 11 and 11A depicts a particular example of the epitaxial structure shown in FIG. 10;

FIG. 12 depicts schematically a manufacturing method of a fifth embodiment according to the present invention;

FIG. 13 depicts schematically a structure of a fifth embodiment according to the present invention;

FIG. 14 depicts a particular example of the epitaxial structure shown in FIG. 13;

FIG. 15 depicts schematically a structure of a six embodiment according to the present invention; and

FIG. 16 is an example of a chromaticity diagram resulted from a prior white colored LED.

### DETAILED DESCRIPTION OF PREFERRED EMBODIMENTS

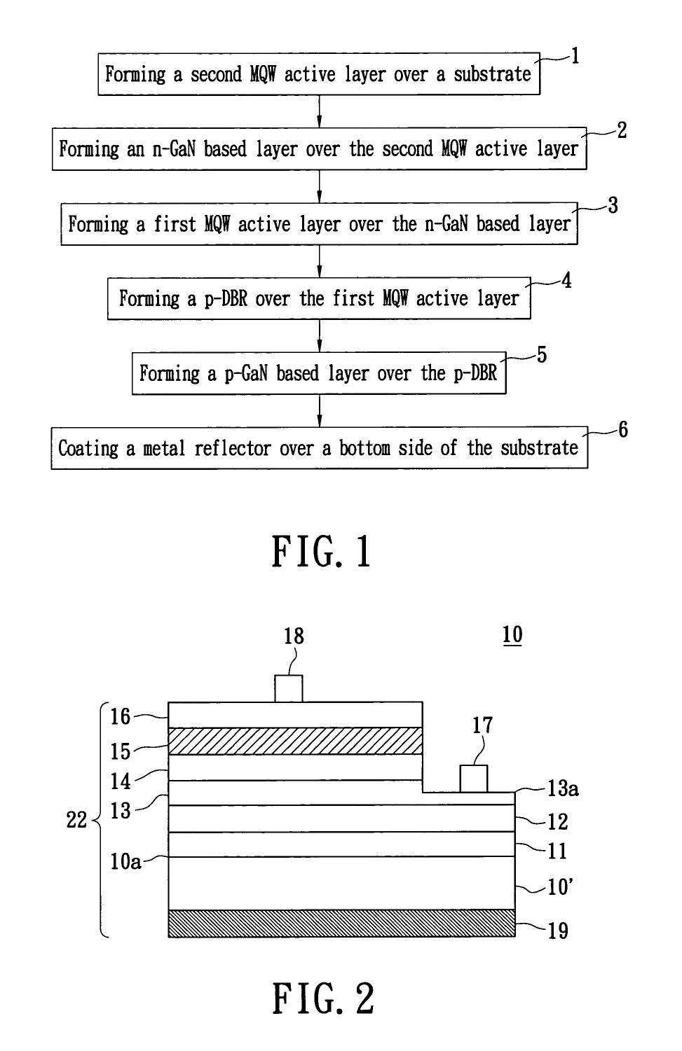

The present invention is related to a light-emitting device capable of emitting a specified colored light, and particularly for a white colored LED and the corresponding manufacturing method. In the following, the description will be mainly made for the white colored LED. The specified colored LED may be readily understood through the description for the white colored LED since they are made in principle in a similar manner. In a preferred embodiment, the manufacturing method for a light-emitting device of a white colored light-emitting device (LED) according to the present invention comprises the following steps. In appreciating the preferred embodiment, please refer directly to FIG. 1 to 3 and 3A.

Step 1: forming a second MQW active layer over an upper side of a substrate, performed after a buffer layer is formed on said substrate, wherein the second MQW active layer is made of GaN/InGaN (an alternating semiconductor layer structure familiar to those skilled in the art), the substrate can be such as sapphire, silicon carbide (SiC) and gallium nitride (GaN) for the consideration that a GaN based material is chosen thereon, wherein the second MQW active layer is chosen in terms of In dopant concentration so that a second light with a wavelength of 550 nm to 650 nm is emitted with the presence of an electric bias applied on the device. However, it does not mean the second light is excited directly by the applied voltage and it is actually excited by a first light, as will be described in more detailed through the following description. The buffer layer may be composed of some layers, such as a coarse grain nucleation layer made of GaN and an undoped GaN layer. The nucleation layer is a low temperature layer, i.e. formed under a low temperature condition, about 500-550° C.; has a thickness of 200-400 Å and will be referred to as an LT-GaN layer herein. The undoped GaN is a high temperature layer, formed under a temperature of 1020-1040° C. and has a thickness of 0.2-2 μm, and will be termed as an HT-GaN layer. These buffer layers may be formed by molecular beam epitaxy (MBE), metal organic chemical vapor deposition (MOCVD) and some other suitable technologies, currently in existence or set forth in the future. Besides, the forming conditions of the second MQW active layer, GaN layer and InGaN layer may be chosen as long as the specific function, giving off a blue light, is achieved. In terms of forming technology, the GaN and InGaN layers in the MQW active layer may be produced through atomic layer epitaxy (ALE) technology.

Step 2: forming an n-GaN based epitaxial layer over said second MQW active layer 12, by such as MBE and MOCVD. In forming such n-GaN based epitaxial layer, the temperature is 1020° C.-1040° C. and the formed thickness is 2-8 μm.

Step 3: forming a first MQW layer over said n-GaN based epitaxial layer, wherein said first MQW active layer emits a first light with a wavelength of 450 nm to 510 nm with the presence of the above-mentioned applied voltage. Similar to the second MQW layer, the In concentration, process conditions and thickness of the first MQW layer are chosen so that the first MQW layer generates a first light with a wavelength of 450 nm-510 nm.

Step 4: forming a p-type distributed Brag reflector (DBR) over said first MQW active layer. In a preferred embodiment of the present invention, the p-type DBR is AlGaN/GaN. The thickness is 0.1-0.5 μm and the process temperature is 960-1000° C. The reflectance of the DBR may be 50-80%.

Step 5: forming a p-GaN based layer over said p-type DBR and etching away a portion of said n-GaN layer, said first MQW active layer, said p-type DBR and said p-GaN based layer whereby said n-GaN layer has an exposing region and an n-type electrode may be disposed over said exposing region and a p-type electrode may be disposed over said p-GaN layer. The p-GaN based layer can be formed by such as MBE and MOCVD, under the process conditions of a temperature of 1020° C.-1040° C. and a thickness is 2-8, m. On the other hand, the n- and p-type electrodes may each be formed by such as sputtering, vaporizing and E-gun technologies, and the adoptive electrode material may be well-conductive metal of all appropriate kinds, such as aluminum and copper, and may preferably have good light transparency (to the light generated by the device), such as thin Ni/Au layer. It is to be noted that although the formations of the electrodes 17 and 18 are absent from the recitation of this step and FIG. 1, they are in effect successively formed.

Step 6: coating a metal reflector over a bottom side of the substrate. The coating method may be such as sputtering, vaporizing and E-gun technologies. In undertaking the coating step, the bottom side of the substrate may be polished to a reduced thickness, 50 μm to 300 μm, and then coated with the metal reflector, from a larger thickness where the preceding 5 steps are executed. The metal reflector is made of a suitable metal so that a specified reflector, such as having a desired reflectivity, such as greater than 90%, may be achieved and has a thickness of 50 Å to 10 μm.

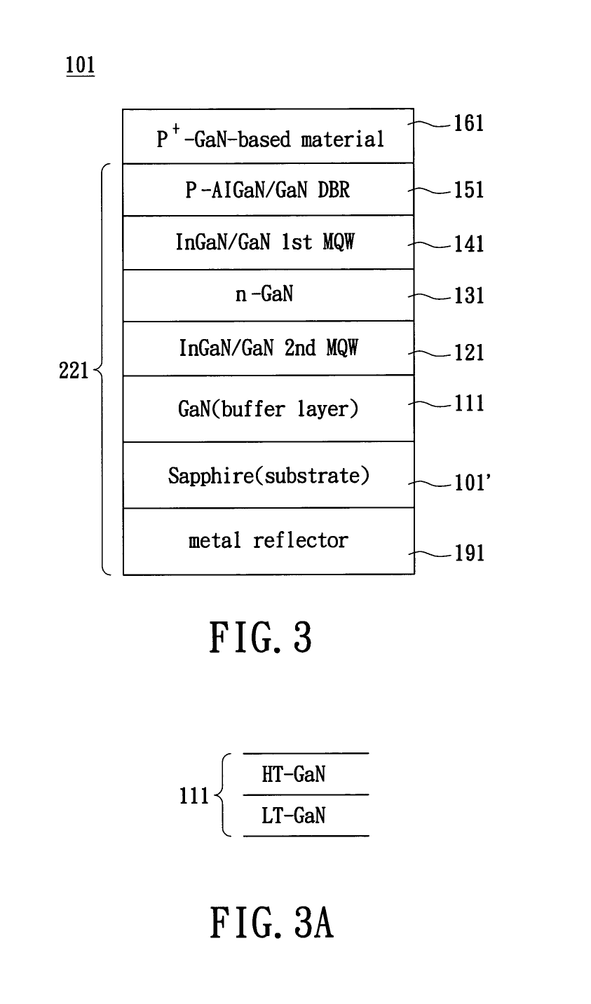

In FIG. 2, the light-emitting device 10 manufactured by the above-recited method of the present invention is shown. The device 10 comprises a resonant cavity structure 22, a contact layer 16, an n-type metal electrode 17 and a p-type metal electrode 18, wherein said resonant cavity 22 formed in sequence by, from bottom to top, a metal reflector 19, a substrate 10′, a buffer layer 11, a second MQW active layer 12, an n-GaN based layer 13, a first MQW active layer 14 and a p-type distributed Bragg reflector (DBR) 15, wherein the substrate 10′ may be such as sapphire, gallium nitride (GaN) and silicon carbide (SiC). The buffer layer 11 is provided as an intermediate layer of the substrate 10′ and the second MQW active layer 12 for some reasons, such as better lattice matching. As also described in the above, the buffer layer 11 may be composed of some layers. The contact layer 16 is a p-GaN based layer and formed over said p-type DBR 15 for contact with a corresponding electrode 18. The p-type metal electrode 18 is disposed over said p-GaN layer 16 for electricity feed, while the n-type metal electrode 17 is disposed over an exposing region 13a of the n-GaN layer 13. In FIGS. 3 and 3A, a particular example of the device depicted in FIG. 2 is shown. As shown in FIG. 3, the p-GaN based layer 161 is heavily doped for better ohmic contact with the upper metal electrode and may be replaced by a p-InGaN or a p-AlInGaN layer.

Since the resonant cavity 22 is provided in the device 10, the first light may move back and forth in the cavity 22 and excite the second MQW layer to generate the second light. Therefore, the second light is generated not by the applied electric bias directly but by the first light that has been previously excited by the electric bias.

In fact, the wavelengths of the first and the second lights may not be between 450 nm-510 nm and between the 550 nm-650 nm. The two lights, the first light and the second light, emitted by the two MQW active layers may be alternatively chosen as long as the two lights may mix into a white colored light.

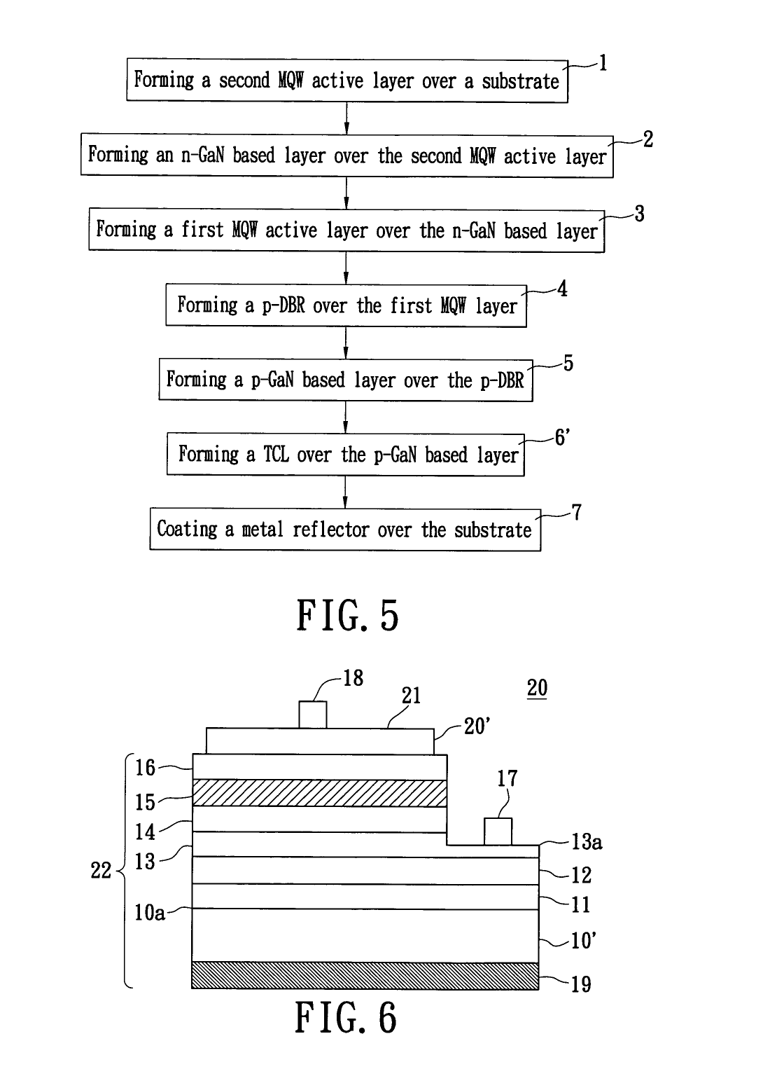

In addition to the above steps described in the preferred method embodiment, the method may add a step of coating a transparent contact layer (TCL) (Step 6′) with a suitable thickness over the contact layer, p-GaN based layer 16, succeeding to Step 5, as is defined as the second method embodiment according to the present invention with the other steps the same, and which is shown in FIG. 5.

The second device embodiment according to the present invention corresponds to the second method embodiment, and which is provided schematically as FIG. 6. It is to be noted that the TCL 20′ is added in the device 20 and has a suitable thickness for compensating for the low mobility of the majority of carriers, holes, and uniformly spreading the electrical charges in the neighborhood of the p-type electrode to the entire contact layer, p-GaN based layer 16 and thus promoting luminous efficiency of the device 20. The so-called “suitable thickness” of the TCL 20′ means a thickness that may lead the TCL 20′ to be efficient in light extraction, which depends on the material adopted as the TCL 20′. The TCL 20′ comprises Au/Ni (first formed with an Au layer and then with a Ni layer) and other conductive and transparent materials (transparent to a light having a wavelength ranging from 400 nm-700 nm). Further, TCL 20′ may be a n-TCL or a p-TCL.

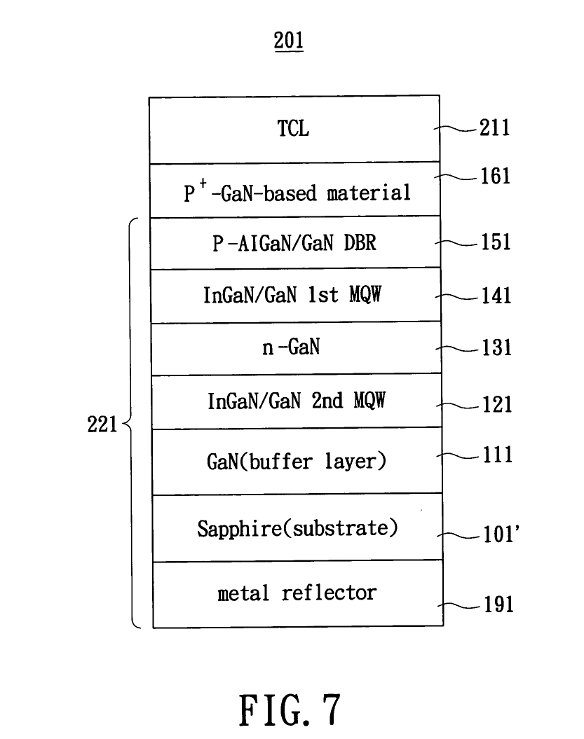

For a specific device illustration, FIG. 7 shows a particular example of the device of FIG. 6 as the device 201. As is with the p-GaN based layer 371 of FIG. 3, the p-GaN based layer 161 is heavily doped for better ohmic contact with the upper metal electrode and may be replaced by a p-InGaN or a p-AlInGaN layer.

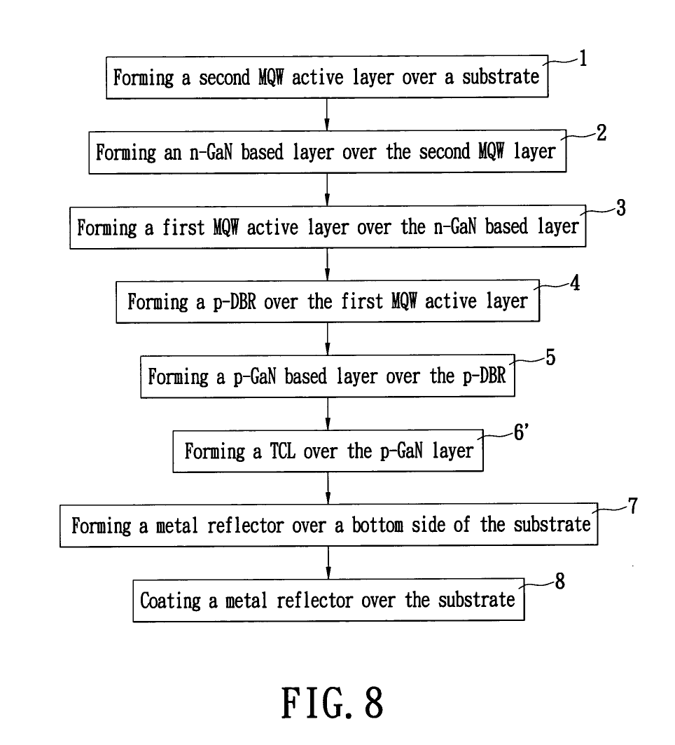

Further, the TCL may be subject to a surface treatment at its upper surface. The surface treatment is applied so as to minimize the portions of the generated light back into the light-emitting device. The surface treatment applied may be forming a roughened surface or particularly textured surface on the TCL surface. Therefore, the third method embodiment, shown in FIG. 8, according to the present invention is intended to cover this step, Step 8.

The third device embodiment according to the present invention corresponds to the third method embodiment. The illustration for the particular textured surface is omitted in the drawings, but may be generally referenced to the label 21 in FIG. 6, the second device embodiment of the present invention.

The metal reflector is not the only choice for acting as the lower reflecting component for the resonant cavity. Alternatively, an n-type DBR may be otherwise used as the lower reflecting component. The fourth to sixth embodiments of the present invention, an n-type DBR is used for the resonant cavity instead of the metal reflector used in the first three embodiments.

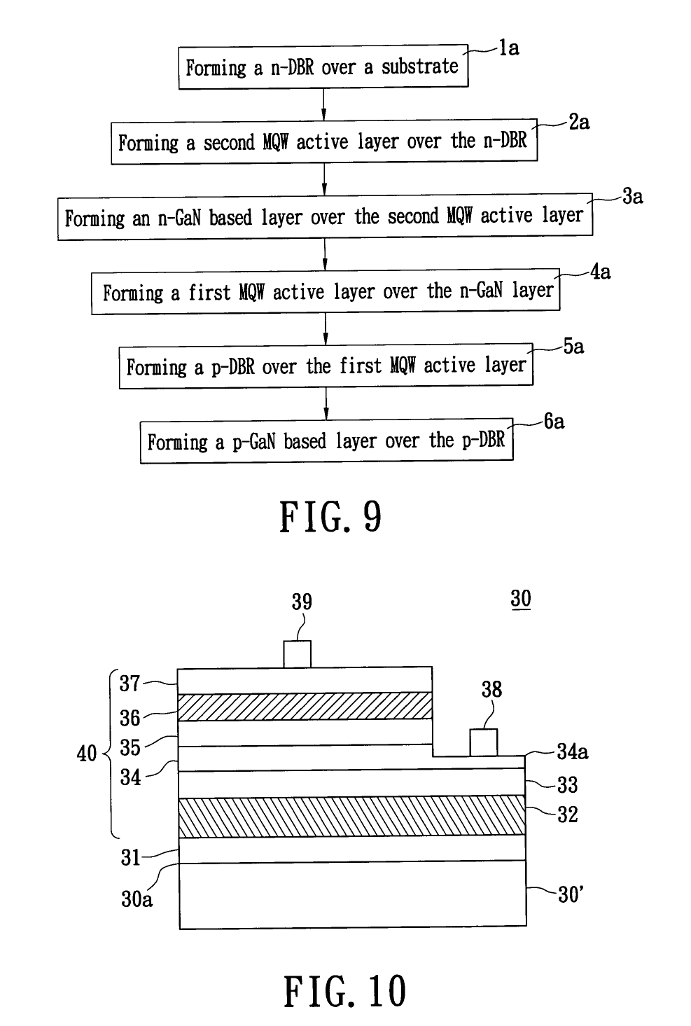

In the fourth method embodiment shown in FIG. 9 according to the present invention, Step 1a is included to form an n-type DBR over a substrate as the lower reflecting component and the step of formation of the metal reflector in the above embodiments is removed. At the time, the resonant cavity is bounded by the n-type DBR and the p-type DBR without a substrate disposed therein, which is otherwise adopted regime for the cavity structure. Because the substrate is not layered in the resonant cavity, the substrate may be a material not transparent, such as silicon, in addition to the materials mentioned above for the substrate.

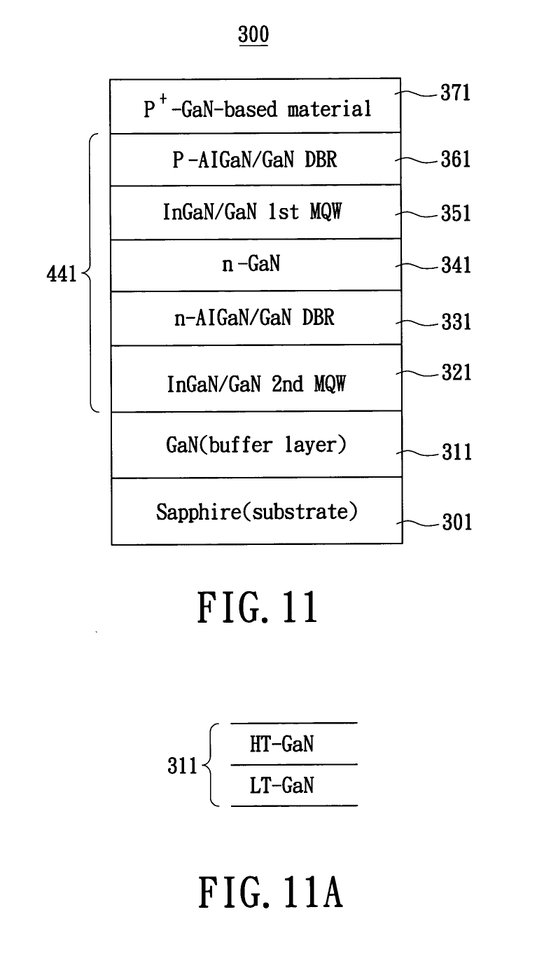

The fourth device embodiment according to the present invention corresponds to the fourth method embodiment, and which is shown schematically as FIG. 10. Further, FIG. 11 and FIG. 11A are a particular example of the device of FIG. 10 and provided herein for better understanding.

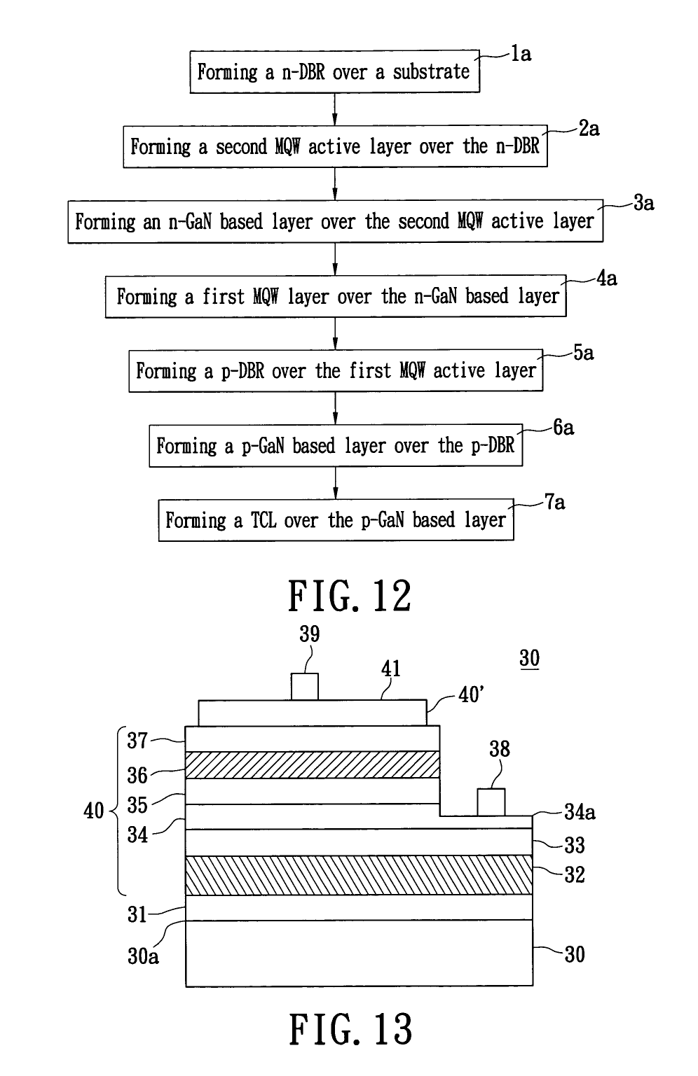

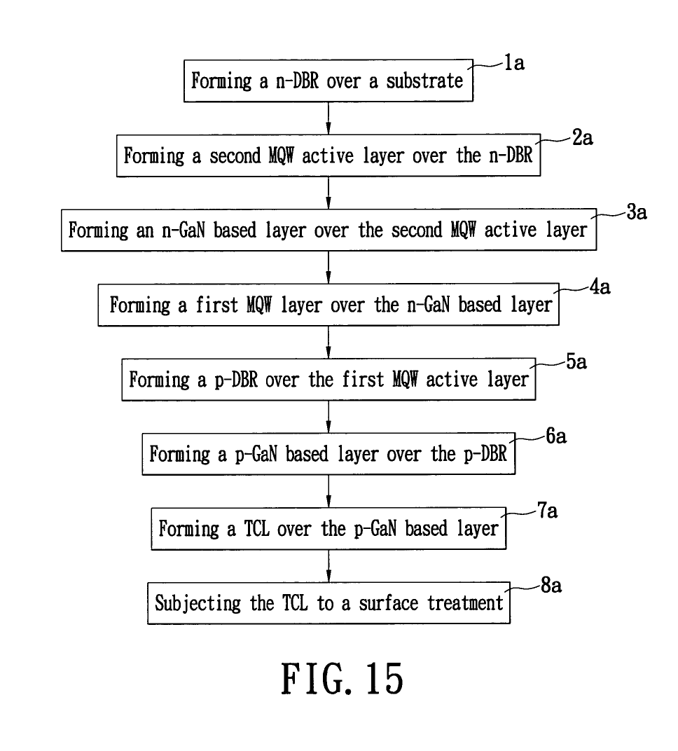

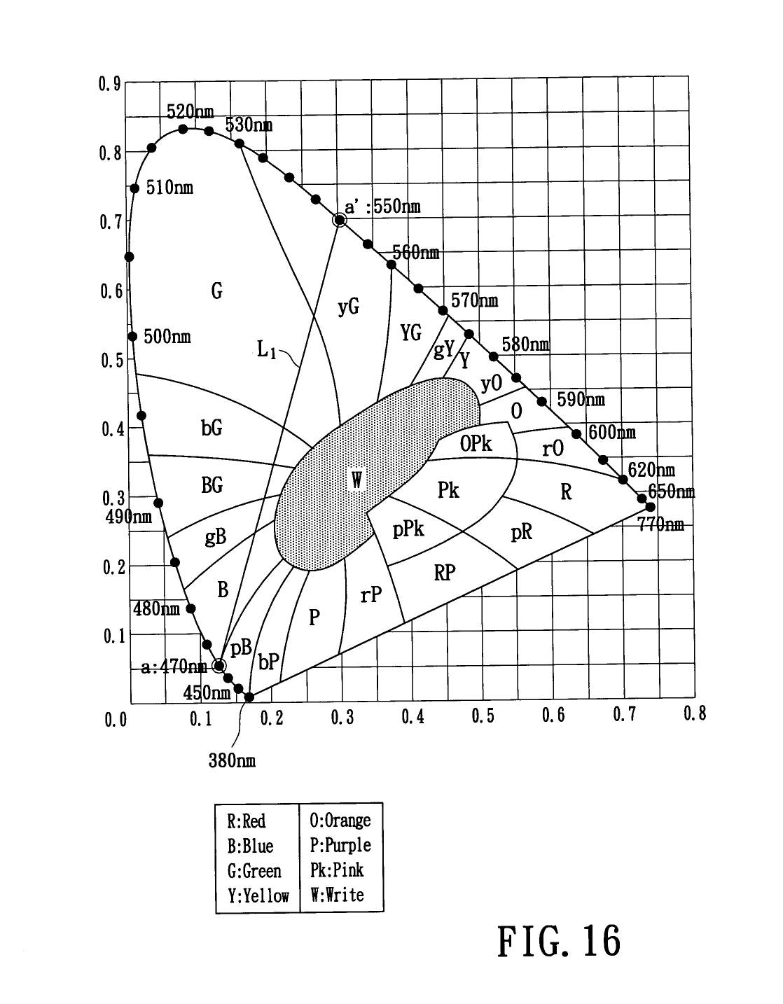

In the case of n-type DBR used, the steps of forming a TCL and subjecting its surface to a surface treatment may also be added in the forming of the device, which are designated as the fifth and sixth method embodiments respectively, corresponding to FIG. 12 and FIG. 15.

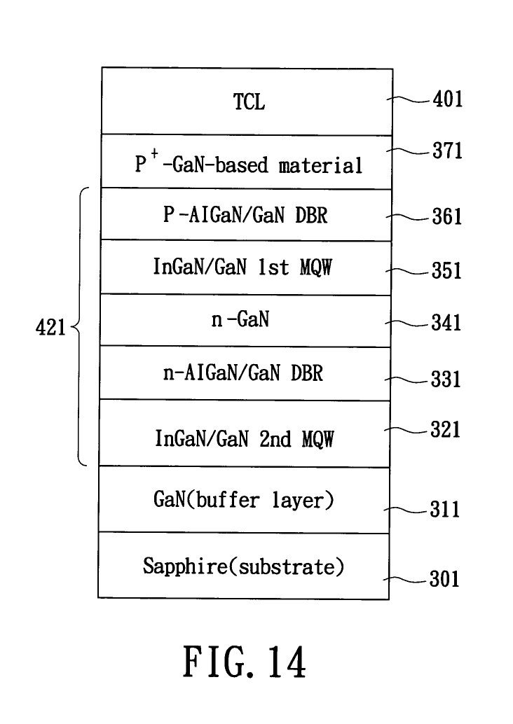

The fifth and sixth device embodiments correspond to the fifth and sixth method embodiments. The former is shown in FIG. 14 while the latter is omitted here for simplicity reason.

The white colored LED produced according to the present invention may be achieved by arranging the inventive light-emitting device with bonding wires for application of an electrical power and packaging the LED, which is ordinary to those persons skilled in the art and will be omitted herein.

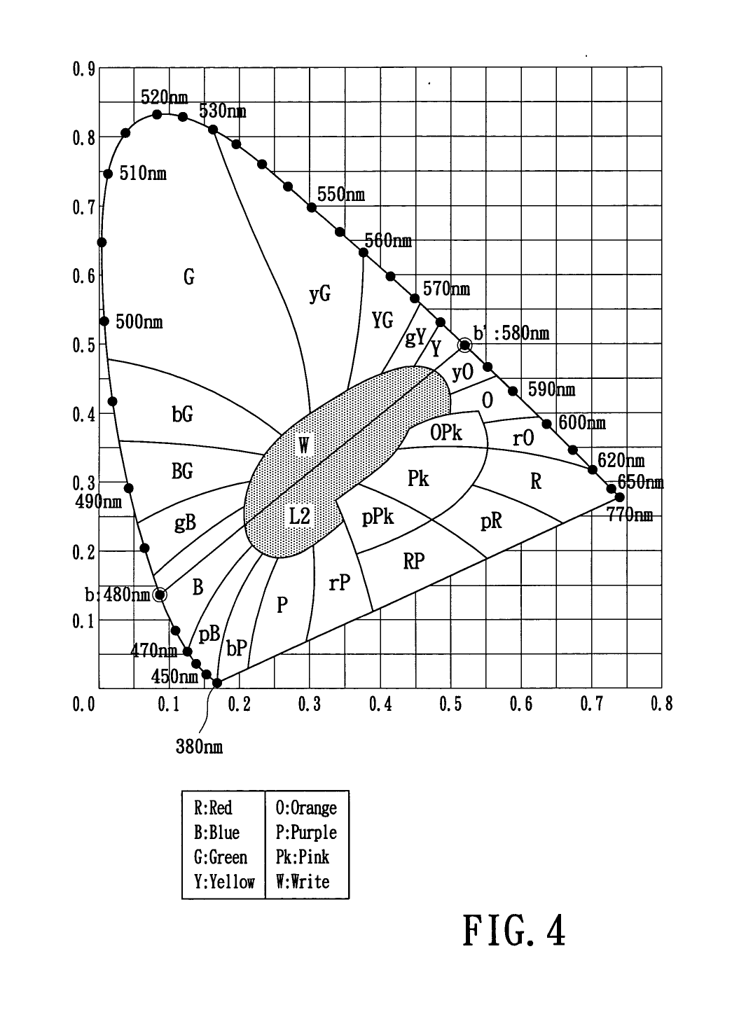

With the white colored LED provided by the present invention, a chromaticity diagram obtained therethrough is like the one shown in FIG. 4. When the first light generated by the first MQW active layer is set to have a wavelength of about 480 nm, and the second light generated by the second light a wavelength of about 580 nm, the points b (corresponding to 480 nm) and b′ (corresponding to 580 nm) may connect into a line L2 exactly crossing the white light area W. Accordingly, the generated light resulted from mixing of the blue and yellow lights observed from the top of the p-GaN based layer may exactly be deemed as a natural light.

Besides, formations of electrodes and the corresponding etching in the above-mentioned method embodiments are not detailedly given in the corresponding drawings and specification in the above method embodiments, yet they are necessary in providing the light-emitting device with exciting electricity and thus emitting lights, which is apparent to those skilled in the art. In fact, the electrodes are successively formed after the etching. In adding the electrodes, the p-type electrode may be directly or indirectly formed over the p-GaN based layer by sputtering, vaporizing and E-gun technologies. However, the n-type electrode may not be directly provided on the entire n-GaN based layer, which may violate the p-n junction structure. In this regard, an etching step, such as a dry etching, such as chlorine plasma etching, or other suitable etching technologies, may be conducted on a portion of the p-GaN based layer, the p-type DBR and the first QWM layer so that a room of an exposing region of the n-GaN based layer may be left for disposition of the n-type electrode. Although the formation of electrodes and the accompanying etching can not be seen in the flowcharts in the drawings, they may be understood through, for example, the device structure 10 of FIG. 2.

It is to be noted that it is easy for those skilled in the art to undertake a variation on the inventive structure with reference to the foregoing embodiments. For example, the layer number in the first and second QWM active layers may not be 2 but others and the corresponding emitted lights may mix into any color of light as long as its corresponding implementation may be put into effect. And thus, the light mixing may come in various ways and the mixed light may be some other colors. All these modifications are deemed within the spirit of the present invention provided the mechanism or principle of the white or other colored lights are similar.

Therefore, while the invention has been described by way of example and in terms of preferred embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a white colored light-emitting device (LED), comprising:
(a) forming a second MQW active layer over an upper side of a substrate, performed after a buffer layer formed on said substrate, and wherein said second MQW active layer comprises a material so that said second MQW active layer emits a second light when excited;
(b) forming an n-GaN based epitaxial layer over said second MQW active layer;
(c) forming a first MQW layer over said n-GaN based epitaxial layer, wherein said first MQW active layer comprises a material so that said first MQW active layer emits a first light with a presence of an electric power applied, and wherein said second light has a longer wavelength than a wavelength of said first light, and said first and second lights mix into a white colored light;
(d) forming a p-type distributed Brag reflector (DBR) over said first MQW active layer;
(e) forming a p-GaN based layer over said p-type DBR, etching away a portion of said n-GaN based, said first MQW active, said p-type DBR and said p-GaN based layers whereby said n-GaN based layer has an exposing region and disposing an n-type electrode over said exposing region of said n-GaN based layer and a p-type electrode over said p-GaN based layer, said electric power is applied between said p-type and n-type electrodes; and
(f) coating a metal reflector over a bottom side of said substrate.

2. The method as in claim 1, wherein said second light has a wavelength of 550-650 nm while said first light has a wavelength of 450-510 nm.

3. The method as in claims 1, wherein said p-type DBR is made of a p-GaN based material and wherein said substrate comprises sapphire, silicon carbide (SiC) and gallium nitride (GaN) and wherein said first and second MQW active layer are InGaN/GaN layers.

4. The method as in claims 2, wherein said first and second wavelengths of said first and second lights are obtained by adjustments of said in dopant concentrations of said first and second MQW active layers.

5. A white colored light-emitting device (LED), comprising:
a resonant cavity structure formed with a metal reflector, a substrate formed over said metal reflector, a buffer layer formed over said substrate, a second MQW active layer formed over said buffer layer, an n-GaN based layer formed over said second MQW active layer, a first MQW active layer formed over said n-GaN based layer and a p-type distributed Bragg reflector (DBR) formed over said first MQW active layer, wherein said p-type DBR has a reflectance;
a contact layer comprising a p-GaN based layer and formed over said p-type DBR;
an n-type metal electrode disposed over an exposing region of said n-GaN layer; and
a p-type metal electrode disposed over said contact layer;
wherein said second MQW active layer comprising a material so that said second MQW active layer generates a second light having a second wavelength when excited; while said first active MQW active layer comprises a material so that said first active MQW layer generates a first light having a first wavelength with a presence of an electric power applied between said n-type metal electrode and said p-type metal electrode, and said second wavelength is larger than said first wavelength and said first light and second lights mix into a white colored light.

6. The light-emitting device as in claim 5, wherein said second wavelength is 550-650 nm while said first wavelength ranges between 450 nm to 510 nm.

7. The light-emitting device as in claim 5, wherein said substrate comprises sapphire, silicon carbide (SiC) and gallium nitride (GaN) and wherein said p-type DBR is a p-GaN based material.

8. The light-emitting device as in claim 5, wherein said contact layer is a p-InGaN or a p-AlInGaN layer.

9. The light-emitting device as in claim 5, wherein said reflectance of said p-type DBR ranges from 50% to 80% while said metal reflector has a reflectance of greater than 90% and comprises any kind of metals and alloy thereof.

10. The light-emitting device as e in claim 5, wherein the light-emitting device further comprises a transparent contact layer (TCL) formed over said contact layer and conductive and transparent to a light with a wavelength of 400-700 nm.

11. The method as in claims 6, wherein said first and second wavelengths of said first and second lights are obtained by adjustments of said In dopant concentrations of said first and second MQW active layers.

12. A white colored light-emitting device (LED), comprising:
a substrate comprising sapphire;
an LT-GaN/HT-GaN buffer layer having a first formed low temperature GaN buffer layer on said substrate and a then formed HT-GaN buffer layer on said LT-GaN buffer layer wherein said LT-GaN buffer layer has a thickness of 30 to 500 Å while said HT-GaN buffer layer has a thickness of 0.5 to 6 μm;
an InGaN/GaN second MQW active layer;
an n-GaN semiconductor layer having a thickness of 2 to 6 μm;
an InGaN/GaN first MQW active layer;
a p-AlGaN/GaN distributed Bragg reflector (DBR); and
a p⁺-GaN based semiconductor contact layer having a thickness of 0.2 to 0.5 μm;
an n-type metal electrode disposed over an exposing region of said n-GaN based layer; and
a p-type metal electrode disposed over said p⁺-GaN based semiconductor layer;
wherein said substrate is coated with a metal reflector on a bottom side of said substrate, wherein said metal reflector has a thickness of 50 Å to 10 μm and made of a conductive metal or metal alloy, and
wherein said InGaN/GaN second MQW active layer has a second In dopant concentration so that said second MQW active layer generates a second light having a wavelength of 550-650 nm when excited while said InGaN/GaN first MQW active layer has a first In dopant concentration so that said InGaN/GaN first MQW active layer generates a first light having a wavelength of 450-510 nm when an electric power is applied between said n-GaN semiconductor layer and said p-AlGaN/GaN distributed Bragg reflector (DBR).

13. The light-emitting device as in claim 12, wherein said substrate further comprises silicon carbide (SiC) and gallium nitride (GaN) and has a thickness of 50 μm to 300 μm, and wherein said conductive metal of said metal reflector comprises Ag, Al and other metallic materials.

14. The light-emitting device as in claim 12, wherein said p⁺-GaN based semiconductor layer further comprises a p⁺-InGaN layer or a p⁺-AlInGaN layer.

15. The light-emitting device as in claim 12, wherein said p⁺-GaN based semiconductor layer is further coated with a transparent contact layer (TCL) and said TCL is conductive and transparent to a light having a wavelength of 400 nm to 700 nm and has a thickness so that said first and second lights may properly penetrate through said TCL.

16. A method for manufacturing a white colored light-emitting device (LED) comprising:
(a) forming an n-type DBR on an upper side of a substrate, performed after a buffer layer is formed over said substrate;
(b) forming a second MQW active layer over said n-type DBR, performed after a buffer layer formed on said substrate, wherein said second MQW active layer comprises a material so that said second MQW active layer emits a second light having a second wavelength when excited;
(c) forming an n-GaN based epitaxial layer over said second MQW active layer;
(d) forming a first MQW layer over said n-GaN based epitaxial layer, wherein said first MQW active layer comprises a material so that said first MQW active layer emits a first light having a first wavelength with a presence of an electric power and said first and second lights mix into a white colored light;
(e) forming said p-type distributed Brag reflector (DBR) over said first MQW active layer; and
(f) forming a p-GaN based layer over said p-type DBR, etching away a portion of said n-GaN, said first MQW active, said p-type DBR and said p-GaN layers whereby said n-GaN has an exposing region and disposing an n-type electrode over said exposing region of said n-GaN based layer and a p-type electrode over said p-GaN based layer, wherein said electric power is applied between said n-type electrode and said p-type electrode.

17. The method as in claim 16, wherein said substrate comprises sapphire, silicon carbide (SiC), silicon (Si) and gallium nitride (GaN).

18. The method as in claim 16, wherein said n-type DBR comprises an n-GaN based layer while said p-type DBR comprises a p-GaN based layer.

19. The method as in claim 16, wherein said second wavelength is 550-650 nm while said first wavelength ranges between 450 nm to 510 nm.

20. The method as in claims 19, wherein said first and second wavelengths of said first and second lights are obtained by adjustments of said In dopant concentrations of said first and second MQW active layers.

21. A white colored light-emitting device (LED), comprising:
a substrate having a buffer layer thereon;
a resonant cavity structure formed over said buffer layer comprising an n-type distributed Bragg reflector (DBR) over said buffer layer, a second multi-quantum well (MQW) active layer over said r-type DBR, an n-GaN based layer over said second MQW active layer, a first MQW active layer over said n-GaN based layer and a p-type DBR over said first MQW active layer;
a contact layer comprising a p-GaN based layer and formed over said p-type DBR;
an n-type metal electrode disposed over an exposing region of said n-GaN based layer; and
a p-type metal electrode disposed over said contact layer;
wherein said InGaN/GaN second MQW active layer has a second In dopant concentration so that said second MQW active layer generates a second light having a second wavelength when excited while said InGaN/GaN first MQW active layer has a first In dopant concentration so that said InGaN/GaN first MQW active layer generates a first light having a first wavelength when an electric power is applied between said n-type metal electrode and said p-type metal electrode and said second wavelength is longer than said first wavelength.

22. The light-emitting device as in claim 21, wherein said substrate comprises comprising sapphire, silicon carbide (SiC), silicon (Si) and gallium nitride (GaN).

23. The light-emitting device as in claim 21, wherein said second wavelength is between 550-650 nm and said first wavelength has a wavelength of 450-510 nm.

24. The light-emitting device as in claim 21, wherein said contact layer comprises a p-InGaN layer or a p-AlInGaN epitaxial layer.

25. The light-emitting device as in claim 21, wherein indexes of refraction of said n-type DBR and p-type DBR are both less than 90%, and are formed of n-GaN based layer and p-GaN based layer respectively.

26. The light-emitting device as in claim 21, wherein said light-emitting device further comprises a TCL formed over said contact layer and transparent to a light with a wavelength of 400-700 nm.

27. The light-emitting device as in claims 23, wherein said first and second wavelengths of said first and second lights are obtained by adjustments of said In dopant concentrations of said first and second MQW active layers.

28. A white colored light-emitting device (LED) structure, comprising:
an LT-GaN/HT-GaN buffer layer having a first formed LT-GaN buffer layer on a substrate and a then formed HT-GaN buffer layer on said LT-GaN buffer layer, wherein said LT-GaN buffering has a thickness of 30 to 500 Å while said HT-GaN buffer layer has a thickness of 0.5 to 6 μm;
an n-AlGaN/GaN distributed Bragg reflector (DBR);
an InGaN/GaN second MQW active layer;
an n-GaN semiconductor layer having a thickness of 2 tO 6 μm;
an InGaN/GaN first MQW active layer;
a p-AlGaN/GaN DBR;
a p⁺-GaN based semiconductor layer having a thickness of 0.2 to 0.5 μm; an n-type metal electrode disposed over an exposing region of said n-GaN based layer; and
a p-type metal electrode disposed over said p⁺-GaN based semiconductor layer;
wherein said InGaN/GaN second MQW active layer has a second In concentration so that said InGaN/GaN second MQW active layer generates a second light having a second wavelength between 550-650 nm when excited while said InGaN/GaN first MQW active layer has a first In dopant concentration so that said In GaN/GaN first MQW active layer generates a first light having a first wavelength between 450-510 nm with a presence of an electric power applied between said p-type metal electrode and said n-type metal electrode, and said first light and said second light mix into a white light.

29. The light-emitting device as in claim 28, wherein said substrate comprises sapphire, silicon carbide (SiC), silicon (Si) and gallium nitride (GaN).

30. The light-emitting device as in claim 28, wherein said contact layer comprises a p-InGaN layer or a p-AlInGaN epitaxial layer.

31. The light-emitting device as in claim 28, wherein indexes of refraction of said n-type DBR and p-type DBR are both less than 90%, and are formed of n-GaN based layer and p-GaN based layer respectively.

32. The light-emitting device as in claim 28, wherein said light-emitting device further comprises a TCL formed over said contact layer and transparent to a light with a wavelength of 400-700 nm.

32. A light-emitting device (LED) capable of emitting a light with a specified wavelength, comprising:
a resonant cavity structure comprising a substrate, a buffer layer on said substrate, a lower n-type reflecting semiconductor layer over said buffer layer, a second MQW active layer over said lower n-type reflecting semiconductor layer, an n-GaN based layer over said second MQW active layer, a first MQW active layer over said second MQW active layer and an upper p-type reflecting semiconductor layer over said first MQW active layer;
a contact layer formed over said p-type DBR, wherein said contact layer comprising a p-GaN based layer;
an n-type metal electrode disposed over an exposing region of said n-GaN layer; and
an p-type metal electrode disposed over said contact layer;
wherein said second MQW active layer comprising a material so that said second MQW active layer generates a second light with a second wavelength when excited; while said first active MQW active layer comprises a material so that said first active MQW layer generates a first light with a first wavelength in response to a presence of an electric power applied between said n-type metal electrode and said p-type metal electrode, and said second wavelength is longer than said first wavelength.

34. The light-emitting device as in claim 33, wherein said second MQW active layer comprises an InGaN/GaN layer with a second In dopant concentration while said first MQW active layer comprises an InGaN/GaN layer with a first In dopant concentration and wherein said first and second wavelengths of said first and second lights are obtained by adjustments of said first and second In dopant concentrations.
